(19) United States
(12) Patent Application Publication
(10) Pub. No.: US 2008/0080249 A1
(43) Pub. Date: Apr. 3, 2008

(54) NON-VOLATILE MEMORY, FABRICATING METHOD AND OPERATING METHOD THEREOF

(75) Inventors: Shi-Hsien Chen, Hsinchu City (TW); Chao-Wei Kuo, Taipei City (TW); Saysamone Pittikoun, Hsinchu County (TW); Michael Yingli Liu, Chiayi City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(73) Assignee: POWERCHIP SEMICONDUCTOR CORP., Hsinchu (TW)

(21) Appl. No.: 11/762,084

(22) Filed: Jun. 13, 2007

(30) Foreign Application Priority Data
Oct. 3, 2006 (TW) 95136686

(51) Int. Cl. G11C 11/34; H01L 29/792

(52) U.S. Cl. 365/185.18; 257/324; 438/128; 257/E29.309

(57) ABSTRACT

A non-volatile memory having a memory cell formed on a substrate is provided. A trench is formed in the substrate. The memory cell has a first gate, a second gate, a charge storage layer, a first source/drain region and a second source/drain region. The first gate is disposed in the trench of the substrate. The second gate is disposed on the substrate at one side of the trench. The charge storage layer is disposed between the first gate and the substrate and between the second gate and the substrate. The first source/drain region is disposed in the substrate at the bottom of the trench. The second source/drain region is disposed in the substrate at one side of the second gate.

### CROSS-REFERENCE TO RELATED APPLICATION

This application claims the priority benefit of Taiwan application serial no. 95136686, filed Oct. 3, 2006. All disclosure of the Taiwan application is incorporated herein by reference.

### BACKGROUND OF THE INVENTION

1. Field of the Invention

The present invention relates to a semiconductor device, and more particularly, to a non-volatile memory, and a manufacturing method and an operating method thereof.

2. Description of Related Art

Among many kinds of memory products, non-volatile memory is a type of memory that allows multiple data writing, reading and erasing operations. The stored data will be retained even after power to the device is cut-off. With these advantages, non-volatile memory has become one of the most widely adopted memory devices for personal computer and electronic equipment.

In a typical EEPROM, the doped polysilicon is used to make the floating gate and the control gate. However, when there is defect in the tunneling oxide under the doped polysilicon floating gate layer, current leakage will be occurred in the device and the reliability of the device will be affected.

Accordingly, in conventional technologies, sometimes the polysilicon floating gate is replaced by a charge trapping layer whose material is, for example, silicon nitride. The silicon nitride charge trapping layer usually has a silicon oxide layer on its top surface and bottom surface respectively, thus forming an oxide-nitride-oxide (ONO) composite layer. The device is usually called silicon/oxide-nitride-oxide/silicon (SONOS) device. As silicon nitride has an electron-trapping characteristic, the electrons injected into the charge trapping layer may concentrate in a partial area of the charge trapping layer. Therefore, SONOS device has little sensitivity to the defect of the tunneling oxide layer, and the leakage current in device is more unlikely to occur.

A SONOS memory cell can respectively store a bit in the silicon nitride layer of ONO layer at the source side and drain side. However, if a bit is stored at the drain side, the second bit effect will be produced in the process of reverse reading. That is, the originally stored bit will affect the forward reading and enhance the barrier so as to increase the threshold voltage (Vt) of the forward reading. So far, the solution replying to the aforesaid problem is to increase the drain voltage (Vd) so as to enhance the drain-induced barrier lowing (DIBL). However, since the dimension of device is shrinking, the excessive drain voltage will result in the operation difficulties.

### SUMMARY OF THE INVENTION

Accordingly, the present invention provides a non-volatile memory and manufacturing method and operating method thereof. Such non-volatile memory may store 2-bit data in a single memory cell, thus improving the integrity of the device.

The present invention provides a non-volatile memory and manufacturing method and operating method thereof. Such a method is simple and increases the process window.

The present invention provides a non-volatile memory and manufacturing method and operating method thereof. Such a method can avoid the second bit effect and reduce the operating voltage.

The present invention provides a non-volatile memory containing a first memory cell disposed on the substrate. A trench is in the substrate. The first memory cell consists of a first gate, a second gate, a charge storage layer, a first source/drain region and a second source/drain region. The first gate is disposed in the trench. The second gate is disposed on the substrate at one side of the trench. The charge storage layer is disposed extensively between the first gate and the substrate, and between the second gate and the substrate. The first source/drain region is disposed in the substrate at the bottom of the trench. The second source/drain region is disposed in the substrate at one side of the second gate.

According to one embodiment of the present invention, the memory further includes a top dielectric layer. The top dielectric layer is disposed between the first gate and the charge storage layer and between the second gate and the charge storage layer. The material of the top dielectric layer includes silicon oxide.

According to one embodiment of the present invention, the memory further includes a bottom dielectric layer. The bottom dielectric layer is disposed between the first gate and the substrate and between the second gate and the substrate. The material of the bottom dielectric layer includes the silicon oxide.

According to an embodiment of the present invention, the material of the aforesaid charge storage layer includes silicon nitride.

According to an embodiment of the present invention, the aforesaid material of the first gate and the second gate includes doped polysilicon.

According to an embodiment of the present invention, the aforesaid first gate fills the trench.

According to one embodiment of the present invention, the memory further includes an insulating layer. The insulating layer is disposed on the first gate and isolates the first gate from the second gate.

According to one embodiment of the present invention, the aforesaid second gate is a conductive spacer disposed at the sidewall of the insulating layer.

According to one embodiment of the present invention, the memory further includes a dielectric layer. The dielectric layer is disposed in the charge storage layer, dividing the charge storage layer into the first portion and the second portion. The first portion is disposed between the first gate and the substrate; the second portion is disposed between the second gate and the substrate.

According to one embodiment of the present invention, the memory further includes a second memory cell. The structure of the second memory cell is the same as the one of the first memory cell, wherein the second memory cell and the first memory cell are configured mirror-systematically.

According to one embodiment of the present invention, the aforesaid first memory cell and the second memory cell share the first source/drain region or the second source/drain region.

According to one embodiment of the present invention, the second gates of the first memory cell and of the second memory cell are electrically connected.

According to one embodiment of the present invention, the aforesaid first memory cell and the second memory cell share the first source/drain region; the first gates of the first memory cell and of the second memory cells are electrically connected.

According to one embodiment of the present invention, the charge storage layers between the first gate and the substrate and between the second gate and the substrate can respectively store one-bit of data.

The present invention relates to a non-volatile memory consisting of a plurality of memory cells, the first bit lines, the second bit lines, the word lines, and control gate lines. A plurality of memory cells are disposed on the substrate and arranged to form a row/column array. Each memory cell consists of a first source/drain region, a second source/drain region, a first gate, a second gate, and a charge storage layer. The first source/drain region and the second source/drain region are disposed in the substrate. The first gate and the second gate are serially disposed between the first source/drain region and the second source/drain region, and the first gate and the second gate are electrically insulated. The charge storage layer is disposed extensively between the first gate and the substrate and between the second gate and the substrate. The two adjacent memory cells in column direction are disposed mirror-systematically and share the first source/drain region or the second source/drain region. The first gates of the two adjacent memory cells sharing the first source/drain region in column direction are electrically connected. A plurality of first bit lines are arranged in parallel along the row direction, and each of the first bit lines is connected with the first source/drain region of the memory cells of the same row. A plurality of second bit lines are arranged in parallel along the row direction, and each of the second bit lines is connected with the second source/drain region of the memory cells of the same row. A plurality of word lines are arranged in parallel along the row direction, and each of the word lines is connected to the first gate of the memory cells of the same row. A plurality of control gate lines are arranged in parallel along the column direction, and each of the control gate lines is connected to the second gate of the memory cells of the same column. The memory further includes a plurality of trenches arranged in parallel in the substrate. The trenches are disposed extensively in row direction. The aforesaid first gates are disposed respectively in the trenches. The aforesaid first source/drain regions are respectively disposed in the substrate at the bottom of the trenches. The aforesaid first bit lines are disposed respectively at the bottom of the trenches. The aforesaid word lines respectively fill the trenches.

According to one embodiment of the present invention, the charge storage layers between the first gate and the substrate and between the second gate and the substrate can respectively store one-bit of data.

According to one embodiment of the present invention, the memory further includes a top dielectric layer. The top dielectric layer is disposed between the first gate and the charge storage layer and between the second gate and the charge storage layer. The material of the top dielectric layer includes silicon oxide.

According to one embodiment of the present invention, the memory further includes a bottom dielectric layer. The bottom dielectric layer is disposed between the first gate and the substrate and between the second gate and the substrate. The material of the bottom dielectric layer includes silicon oxide.

According to an embodiment of the present invention, the material of the aforesaid charge storage layer includes silicon nitride.

According to an embodiment of the present invention, the material of the aforesaid first gate and the second gate includes doped polysilicon.

According to one embodiment of the present invention, the memory further includes a plurality of insulating layers. The insulating layers are respectively disposed on the word lines. Each insulating layer isolates the first gate from the second gate.

According to one embodiment of the present invention, each of the second gates is a conductive spacer disposed at the sidewall of each insulating layer.

According to one embodiment of the present invention, the memory further includes a dielectric layer. The dielectric layer is disposed in the charge storage layer, dividing the charge storage layer into the first portion and the second portion. The first portion is located between the first gate and the substrate; the second portion is located between the second gate and the substrate.

According to one embodiment of the present invention, the memory further includes a plurality of isolation doped regions. The isolation doped regions are disposed in the substrate between the control gate lines so as to isolate the two adjacent memory cells of the same row.

In the present invention of the non-volatile memory, the first gate and the second gate are disposed in each memory cell. The charge storage layers between the first gate and the substrate and between the second gate and the substrate can respectively store one bit of data. In other words, the single memory cell in the non-volatile memory of the present invention can store two bits of data.

Moreover, the first gate and the second gate are disposed in each memory cell. Therefore, when operating the memory cells, the different voltage is added to the first gate and the second gate so as to avoid the second bit effect. Besides, the dielectric layer can be disposed in the charge storage layer to isolate the first bit from the second bit so as to avoid the disturbance between the first bit and the second bit.

In the present invention, since a portion of the charge storage layer and the first gate are formed in the trench within the substrate, the size of memory cells can be reduced and the integration of the device can be increased.

The present invention providing a method of fabricating the non-volatile memory includes the following steps. A substrate is provided, and a plurality of trenches are formed in the substrate. The trenches are disposed extensively in a first direction. A plurality of first source/drain regions are formed at the bottom of the trenches. A charge storage layer is formed on the substrate, and a first gate is formed respectively in the trenches. The insulating layer is respectively formed on the first gate, and a plurality of conductive spacers are formed on the sidewall of the insulating layer. A plurality of second source/drain regions are formed in the substrate between the conductive spacers, and inter-layer insulating layers are formed on the second source/drain regions. A conductive layer is formed on the substrate and electrically connected with the conductive spacer. The conductive layer and the conductive spacer are patterned to form a plurality of conductive lines and the second gates thereunder. The conductive lines are disposed extensively in a second direction; the second direction and the first direction are alternately positioned.

According to the embodiment of the present invention, the steps to respectively form the first gates in the trenches are as following. A first conductive layer is formed on the substrate and fills the trenches. Next, a portion of the first conductive layer outside the trenches is removed.

According to an embodiment of the present invention, the steps to remove a portion of the first conductive layer outside the trenches include performing etching back process or the chemical mechanical polishing process.

According to the embodiment of the present invention, the steps to respectively form the insulating layers in the first gates are as following. An insulating material layer is formed on the substrate, and then the insulating material layer is patterned.

According to the embodiment of the present invention, the steps to respectively form the conductive spacer on the sidewall of the insulating layer are as following. A second conductive layer is formed over the substrate. Next, the anisotropic etching process is performed to remove a portion of the second conductive layer.

According to an embodiment of the present invention, when performing the anisotropic etching process to remove a portion of the second conductive layer, the step further includes removing a portion of the charge storage layer to expose the substrate.

According to an embodiment of the present invention, a plurality of isolation doped regions are formed in the substrate between two adjacent conductive lines.

According to an embodiment of the present invention, before the charge storage region is formed on the substrate, a bottom dielectric layer is formed on the substrate. The material of the bottom dielectric layer includes silicon oxide.

According to an embodiment of the present invention, after the charge storage region is formed on the substrate, a top dielectric layer is formed on the charge storage layer. The material of the top dielectric layer includes silicon oxide.

According to an embodiment of the present invention, the material of the charge storage layer includes silicon nitride.

According to an embodiment of the present invention, the material of the first gate and the second gate includes doped polysilicon.

The present invention providing a method of fabricating the non-volatile memory includes the following steps. First, a substrate is provided, and a trench is formed in the substrate. Next, a first source/drain region is formed at the bottom of the trench. After a charge storage layer is formed on the substrate, a first gate is formed in the trench. Then, a second gate is formed over the substrate. The second gate is adjacent to the first gate; the second gate is electrically insulated against the first gate. Afterwards, a second source/drain region is formed in the substrate on one side of the second gate.

According to the embodiment of the present invention, the steps to form the first gate in the trench are as following. A first conductive layer is formed on the substrate and fills the trench. Next, a portion of the first conductive layer outside the trench is removed.

According to an embodiment of the present invention, the steps to remove a portion of the first conductive layer outside the trench include performing etching back process or chemical mechanical polishing process.

According to an embodiment of the present invention, an insulating layer is formed between the first gate and the second gate.

According to an embodiment of the present invention, before the charge storage region is formed on the substrate, a bottom dielectric layer is formed on the substrate. The material of the bottom dielectric layer includes silicon oxide.

According to an embodiment of the present invention, after the charge storage region is formed on the substrate, a top dielectric layer is further formed on the charge storage layer. The material of the top dielectric layer includes silicon oxide.

According to an embodiment of the present invention, the material of the charge storage layer includes silicon nitride.

According to an embodiment of the present invention, the material of the first gate and the second gate includes doped polysilicon.

In the present invention relating to the fabricating method of non-volatile memory, since the first bit line, the second bit line, the word line are formed by self-alignment process, and an additional photolithographic process is not required, the fabricating method of the present invention is simpler and reduces the cost.

Besides, since a portion of the charge storage layer and the first gate are formed in the trench within the substrate, the size of memory cells can be reduced and the integration of the device can be increased. Moreover, the channel length of the memory cells can be adjusted by controlling the depth of the trenches so that the abnormal electrical punch-through in the memory cells can be avoided. In addition, the fabricating method of the non-volatile memory in the present invention is relatively simpler, and the level of integration of a memory cell array can be increased.

The present invention provides an operating method for a non-volatile memory, suitable for the memory cell array structure. The memory cell array includes a plurality of memory cells, a plurality of first bit lines, a plurality of second bit lines, a plurality of word lines and a plurality of control gate lines. Each memory cell includes a first source/drain region and a second source/drain region disposed in the substrate, a first gate and a second gate serially disposed between the first source/drain region and the second source/drain region, and a charge storage layer disposed between the first gate and the substrate and between the second gate and the substrate. The memory further includes a plurality of trenches arranged in parallel in the substrate. The trenches are disposed extensively in row direction. The aforesaid first gates are disposed respectively in the trenches. The aforesaid first source/drain regions are respectively disposed in the substrate at the bottom of the trenches. The first gate is electrically insulated against the second gate. The charge storage layer between the first gate and the substrate is a first bit; the charge storage layer between the second gate and the substrate is a second bit. The two adjacent memory cells in column direction are disposed mirror-systematically and share the first source/drain region or the second source/drain region. The first gates of the two adjacent memory cells sharing the first source/drain region in column direction are electrically connected. A plurality of first bit lines are arranged in parallel along the row direction and each of the first bit lines is connected with the first source/drain region of the memory cells of the same row. A plurality of second bit lines are arranged in parallel along the row direction and each of the second bit lines is connected with the second source/drain region of the memory cells of the same row. A plurality of word lines are arranged in parallel along the row direction, and each of the word lines is connected to the first gate of the memory cells of the same row. A plurality of control gate lines are arranged in parallel along the column direction, and each of the control gate lines is connected to the second gate of the memory cells of the same column. When programming the first bit of a selected memory cell, the applied bias is as following. A first voltage is applied to a selected word line connected with the selected memory cell. A second voltage is applied to a selected control gate line connected with the selected memory cell. A third voltage is applied to a selected first bit line connected with the selected memory cell. A fourth voltage is applied to a selected second bit line connected with the selected memory cell.

A fifth voltage is applied to the substrate. A sixth voltage is applied to the other non-selected first bit lines and second bit lines located at the side of the first bit of the selected memory cell. The other non-selected first bit lines and second bit lines located at the side of the second bit of the selected memory cell are floating. Both the first voltage and the second voltage are higher than the fifth voltage, and the third voltage is higher than the fourth voltage. Under the aforesaid bias, the first bit of the selected memory cell is programmed by channel hot electron injection effect. The sixth voltage prevents the non-selected memory cells located at the side of the first bit of the selected memory cell from being programmed.

According to the operating method of the non-volatile memory in one preferred embodiment of the present invention, the aforesaid first voltage is between 8˜12V. The aforesaid second voltage is between 8˜12V. The aforesaid third voltage is about 5V. The aforesaid fourth voltage is about 0V. The aforesaid fifth voltage is about 0V. The aforesaid sixth voltage is about 5V.

According to the operating method in one preferred embodiment of the present invention, when programming the second bit of the selected memory cell, the applied bias is as following. A seventh voltage is applied to the selected word line connected with the selected memory cell. An eighth voltage is applied to the selected control gate line connected with the selected memory cell. A ninth voltage is applied to the selected second bit line connected with the selected memory cell. A tenth voltage is applied to the selected first bit line connected with the selected memory cell. An eleventh voltage is applied to the substrate. A twelfth voltage is applied to the other non-selected first bit lines and second bit lines located at the side of the second bit of the selected memory cell. The other non-selected first bit lines and second bit lines located at the side of the first bit of the selected memory cell are floating. Both the seventh voltage and the eighth voltage are higher than the eleventh voltage, and the ninth voltage is higher than the tenth voltage. Under the aforesaid bias, the second bit of the selected memory cell is programmed by channel hot electron injection effect. The twelfth voltage prevents the non-selected memory cells located at the side of the second bit of the selected memory cell from being programmed.

According to the operating method in one preferred embodiment of the present invention, the aforesaid seventh voltage is between 8˜12V. The aforesaid eighth voltage is between 8˜12V. The aforesaid ninth voltage is about 5V. The aforesaid tenth voltage is about 0V. The aforesaid eleventh voltage is about 0V. The aforesaid twelfth voltage is about 5V.

According to the operating method in one preferred embodiment of the present invention, when erasing the first bit of the selected memory cell, the applied bias is as following. A thirteenth voltage is applied to the selected word line connected with the selected memory cell. A fourteenth voltage is applied to the selected control gate line connected with the selected memory cell. A fifteenth voltage is applied to the selected first bit line connected with the selected memory cell. A selected second bit line connected with the selected memory cell is floating. A sixteenth voltage is applied to the substrate. The other non-selected first bit lines and second bit lines are floating. The fifth voltage and the thirteenth voltage are used to induce the band to band hot electron injection to erase the first bit of the selected memory cell.

According to the operating method in one preferred embodiment of the present invention, the aforesaid thirteenth voltage is about −5V. The aforesaid fourteenth voltage is about 0V. The aforesaid fifteenth voltage is about 8V. The aforesaid sixteenth voltage is about 0V.

According to the operating method in one preferred embodiment of the present invention, when erasing the second bit of the selected memory cell, the applied bias is as following. A seventeenth voltage is applied to the selected control gate line connected with the selected memory cell. An eighteenth voltage is applied to the selected word line connected with the selected memory cell. A nineteenth voltage is applied to the selected second bit line connected with the selected memory cell. The selected first bit line connected with the selected memory cell is floating. A twentieth voltage is applied to the substrate. The other non-selected first bit lines and second bit lines are floating. The nineteenth voltage and the seventeenth voltage are used to induce the band to band hot electron injection to erase the second bit of the selected memory cell.

According to the operating method in one preferred embodiment of the present invention, the aforesaid seventeenth voltage is about −5V. The aforesaid eighteenth voltage is about 0V. The aforesaid nineteenth voltage is about 8V. The aforesaid twentieth voltage is about 0V.

According to the operating method in one preferred embodiment of the present invention, when reading the first bit of the selected memory cell, the applied bias is as following. A twenty-first voltage is applied to the selected word line connected with the selected memory cell. A twenty-second voltage is applied to the selected control gate line connected with the selected memory cell. A twenty-third voltage is applied to the selected first bit line connected with the selected memory cell. A twenty-fourth voltage is applied to the selected second bit line connected with the selected memory cell. A twenty-fifth voltage is applied to the substrate. A twenty-sixth voltage is applied to the non-selected first bit lines and second bit lines located at the side of the second bit of the selected memory cell. A twenty seventh voltage is applied to the non-selected first bit lines and second bit lines located at the side of the first bit of the selected memory cell. The twenty-first voltage is higher than the threshold voltage of the memory cells without any trapped charges, but lower than the threshold voltage of the memory cells with electric charges. The charge of the twenty-second voltage is sufficient to turn on the channel region under the second gate. The twenty-fourth voltage is higher than the twenty-third voltage. The twenty-sixth voltage is equal to the twenty-fourth voltage. The twenty-seventh voltage is equal to the twenty-third voltage.

According to the operating method in one preferred embodiment of the present invention, the aforesaid twenty-first voltage is about 2.5V. The aforesaid twenty-second voltage is about 6V. The aforesaid twenty-third voltage and the twenty-seventh voltage are about 0V. The aforesaid twenty-fourth voltage and the twenty-sixth voltage are about 1V. The aforesaid twenty-fifth voltage is about 0V.

According to the operating method in one preferred embodiment of the present invention, when reading the second bit of the selected memory cell, the applied bias is as following. A twenty-eighth voltage is applied to the selected control gate line connected with the selected memory cell. A twenty-ninth voltage is applied to the selected word line connected with the selected memory cell. A thirtieth voltage is applied to the selected second bit line connected with the selected memory cell. A thirty-first voltage is applied to the selected first bit line connected with the selected memory cell. A thirty-second voltage is applied to the substrate. A thirty-third voltage is applied to the non-selected first bit lines and second bit lines located at the side of the first bit of the selected memory cell. A thirty-fourth voltage is applied to the non-selected first bit lines and second bit lines located at the side of the second bit of the selected memory cell. The twenty-eighth voltage is higher than the threshold voltage of the memory cells without any trapped charges, but lower than the threshold voltage of the memory cells with electric charges. The charge of the twenty-ninth voltage is sufficient to turn on the channel region under the second gate. The thirty-first voltage is higher than the thirtieth voltage. The thirty-fourth voltage is equal to the thirtieth voltage. The thirty-third voltage is equal to the thirty-first voltage.

According to the operating method in one preferred embodiment of the present invention, the aforesaid twenty-eighth voltage is about 2.5V. The aforesaid twenty-ninth voltage is about 6V. The aforesaid thirty voltage and the thirty-fourth voltage are about 0V. The aforesaid thirty-third voltage and the thirty-first voltage are about 1V. The aforesaid thirty-second voltage is about 0V.

In the operating method for the non-volatile memory of the present invention, the channel hot electron injection effect is used for programming the memory cells, wherein a single bit of a single memory cell is served as a unit. And the band to band hot electron injection is used for erasing of the memory cells. Moreover, since the non-volatile memory cell of the present invention consists of the first gate and the second gate that are electrically isolated, when reading the first bit (or the second bit) of the memory cell, the voltage can be applied to the second gate (or the first gate) so as to completely turn on the channel region under the second gate (or the first gate); therefore, the second bit effect can be suppressed.

In order to the make the aforementioned and other objects, features and advantages of the present invention comprehensible, a preferred embodiment accompanied with figures are described in detail below.

### BRIEF DESCRIPTION OF THE DRAWINGS

FIG. 1A is a top view showing a non-volatile memory according to the present invention.

FIG. 1B shows a schematic cross-sectional view along line A-A′ in FIG. 1A.

FIG. 1C shows a schematic cross-sectional view along line B-B′ in FIG. 1A.

FIG. 2 illustrates the schematic cross-sectional view of the non-volatile memory according to another embodiment of the present invention.

FIG. 3 is a simplified view of circuit illustrating a memory cell array according to one embodiment of the present invention.

FIG. 4A is a schematic view illustrating an embodiment of the programming operation of the non-volatile memory according to the present invention.

FIG. 4B is a schematic view illustrating another embodiment of the programming operation of the non-volatile memory according to the present invention.

FIG. 4C is a schematic view illustrating an embodiment of the erasing operation according to the present invention.

FIG. 4D is a schematic view illustrating another embodiment of the erasing operation according to the present invention.

FIG. 4E is a schematic view illustrating an embodiment of the reading operation of the non-volatile memory according to the present invention.

FIG. 4F is a schematic view illustrating another embodiment of the reading operation of the non-volatile memory according to the present invention.

FIG. 5A to FIG. 5E are schematic cross-sectional views illustrating the manufacturing process of the non-volatile memory according to an embodiment of the present invention.

### DESCRIPTION OF EMBODIMENTS

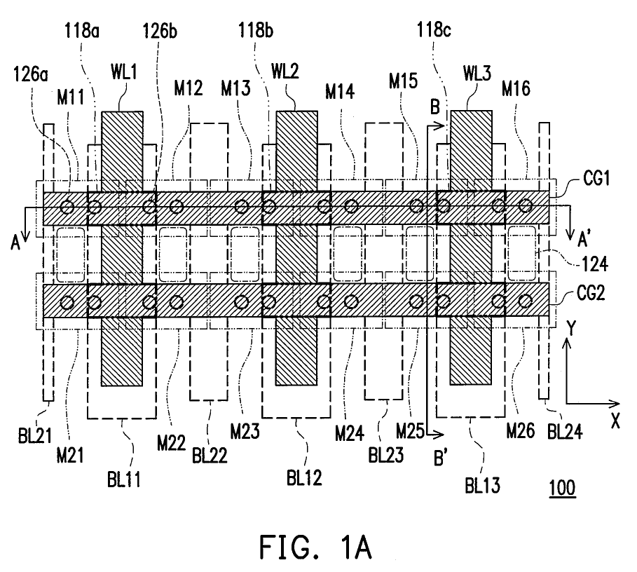

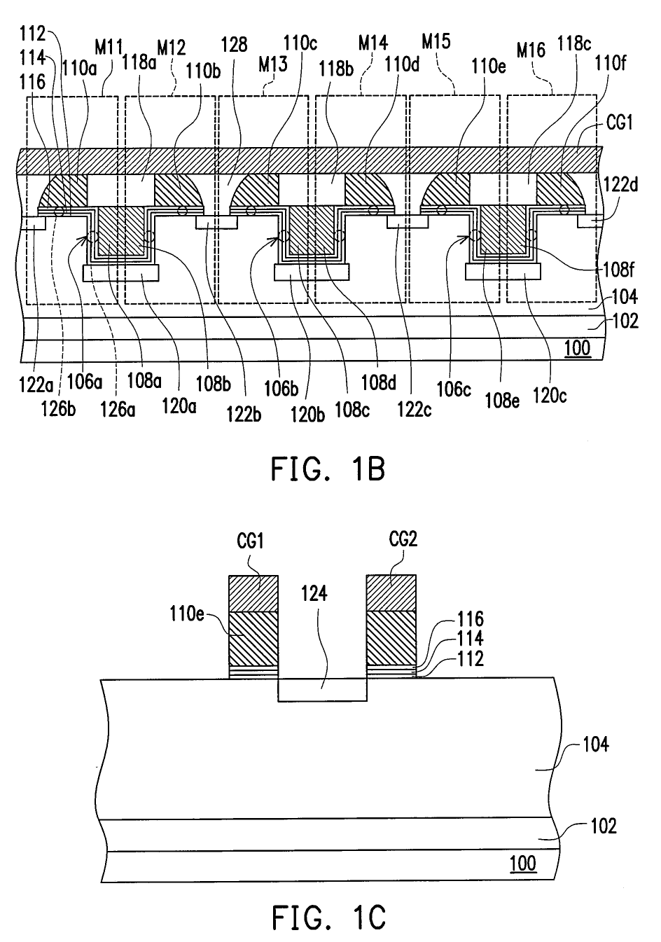

FIG. 1A is a top view showing a non-volatile memory of the present invention. FIG. 1B illustrates a schematic cross-sectional view along line A-A′ in FIG. 1A. FIG. 1C illustrates a schematic cross-sectional view along line B-B′ in FIG. 1A.

Please refer to FIG. 1A, FIG. 1B, and FIG. 1C. The non-volatile memory of the present invention includes substrate 100, a plurality of memory cells M11˜M26, a plurality of word lines WL1˜WL3, a plurality control gate lines CG1˜CG2, a plurality of first bit lines BL11˜BL13, and a plurality of second bit lines BL21˜BL24.

The substrate 100 is, for example, a silicon substrate. A deep N-type well 102 and a P-type deep well 104 are, for example, disposed in the substrate 100. The P-type deep well 104 is, for example, disposed on the deep N-type well 102. Furthermore, the substrate 100 has a plurality of trenches 106a ˜106c. These trenches 106˜106c are arranged in parallel to each other and disposed extensively in Y direction.

The memory cells M11˜M26 are disposed on the substrate 100 and aligned in a row/column array. Since the memory cells M11˜M26 are similar in structure, only the memory cell M11 is explained. The memory cell M11 consists of the first gate 108a, the second gate 110a, the charge storage layer 114, the insulating layer 118a, the first source/drain region 120a, and the second source/drain region 122a.

The first gate 108a is, for example, disposed in the trench 106a and fills the trench 106a. The material of the first gate 108a is, for example, doped polysilicon. The second gate 110a is disposed on the substrate at one side of the trench 106a. The material of the second gate 110a is, for example, doped polysilicon. The second gate 110a is electrically insulated against the first gate 108a. In the non-volatile memory cells of the present invention, each memory cell respectively consists of two gates. The gate disposed in the trench and connected with the first source/drain 120a˜120c is generally called the first gate 108a˜108f. The gate disposed over the substrate and connected with the second source/drain 122a˜122f is generally called the second gate 110a˜110f.

The charge storage layer 114 is disposed extensively between the first gate 108a and the substrate 100, and between the second gate 110a and the substrate 100. The material of the charge storage layer 114 includes the charge trapping material (e.g. silicon nitride) or any other materials that can store the charges.

In each of the memory cells M11˜M16, the charge store layers located between the first gate and the substrate and between the second gate and the substrate can respectively store one bit of data. Take M11 for example, the charge store layer 114 (the first bit 126a) located between the first gate 108a and the substrate 100 can store one bit of data. Similarly, the charge store layer 114 (the second bit 126a) located between the second gate 110a and the substrate 100 can store one bit of data. Therefore, each memory cell of the non-volatile memory in the present invention can store two bits of data.

The bottom dielectric layer 112 and/or the top dielectric layer can be respectively disposed under and/or over the charge store layer 114. The bottom dielectric layer 112 is, for example, disposed between the charge store layer 114 and the substrate 100. The material of the bottom dielectric layer 112 is, for example, silicon oxide. The top dielectric layer 116 is, for example, disposed between the first gate 108a and the charge storage layer 114 and between the second gate 110a and the charge storage layer 114. The material of the top dielectric layer 116 is, for example, silicon oxide.

The first source/drain region 120a is, for example, disposed in the substrate 100 at the bottom of the trench 106a. The second source/drain region 122a is, for example, disposed in the substrate 100 at one side of the second gate 110a. The first source/drain region 120a and the second source/drain region are N-doped region, for example.

The insulating layer 118a is disposed on the first gate 108a. The insulating layer 118a isolates the first gate 108a and the second gate 110a. The material of the insulating layer 118a is, for example, the silicon oxide or silicon nitride. As shown in FIG. 1B, the second gate 110a is disposed on the conductive spacer at the sidewall of the insulating layer 118a.

Two adjacent memory cells M11˜M16 are configured mirror-systematically in X direction (the column direction). Besides, two adjacent memory cells M11˜M16 share the first source/drain region 120a˜120c or the second source/drain region 122a˜122d. The first gates 108a˜108f of two adjacent memory cells M11˜M16 sharing the first source/drain region 120a˜120c are electrically connected with each other by the word lines WL1˜WL3. For example, the memory cells M11 and M12 share the first source/drain region 120a, and the first gate 108a of the memory cell M11 is electrically connected with the first gate 108b of the memory cell M12. The memory cells M12 and M13 share the second source/drain region 122b. The memory cells M13 and M14 share the first source/drain region 120b, and the first gate 108c of the memory cell M13 is electrically connected with the first gate 108d of the memory cell M14. The memory cells M14 and M15 share the second source/drain region 122c. The memory cells M15 and M16 share the first source/drain region 120c, and the first gate 108e of the memory cell M15 is electrically connected with the first gate 108e of the memory cell M16.

A plurality of word lines WL1˜WL3 are arranged in parallel along the Y direction (the row direction), and each of the word lines is connected to the first gate of the memory cells of the same row. For example, the word line WL1 is connected to the first gate of the memory cells M11, M12, M21, and M22. The word line WL2 is connected to the first gate of the memory cells M13, M14, M23, and M24. The word line WL3 is connected to the first gate of the memory cells M15, M16, M25, and M26.

A plurality of control gate lines CG1˜CG2 are arranged in parallel along the X direction (the column direction), and each of the control gate lines is connected to the second gate of the memory cells of the same column. For example, the control gate line CG1 is connected to the second gate 110a˜110f of the memory cells M11˜M16. Besides, a plurality of isolation doped regions 124 are disposed in the substrate 100 between the control gate lines CG1˜CG2 to isolate two adjacent memory cells in the same row.

A plurality of first bit lines BL11˜BL13 are arranged in parallel along the Y direction (the row direction) and connected with the first source/drain region of the memory cells of the same row. Moreover, two adjacent rows of memory cells sharing the first source/drain region share the same first bit line. For example, the first bit line BL11 is connected to the first source/drain region of the memory cells M11, M12, M21 and M22. The first bit line BL12 is connected to the first source/drain region of the memory cells M13, M14, M23 and M24. The first bit line BL13 is connected to the first source/drain region of the memory cells M15, M16, M25 and M26.

A plurality of second bit lines BL21˜BL24 are arranged in parallel along the Y direction (the row direction) and connected with the second source/drain region of the memory cells of the same row. Moreover, two adjacent rows of memory cells sharing the second source/drain region share the same second bit line. For example, the second bit line BL21 is connected to the second source/drain region of the memory cells M11 and M21. The second bit line BL22 is connected to the second source/drain region of the memory cells M12, M13, M22 and M23. The second bit line BL23 is connected to the second source/drain region of the memory cells M14, M15, M24 and M25. The second bit line BL24 is connected to the second source/drain region of the memory cells M16 and M26.

The insulating layer 128 is, for example, disposed between the second bit lines BL21˜BL24 (the second source/drain region 122a˜122d) and the control gate lines CG1˜CG2 to isolate the second bit lines BL21˜BL24 and the control gate lines CG1˜CG2.

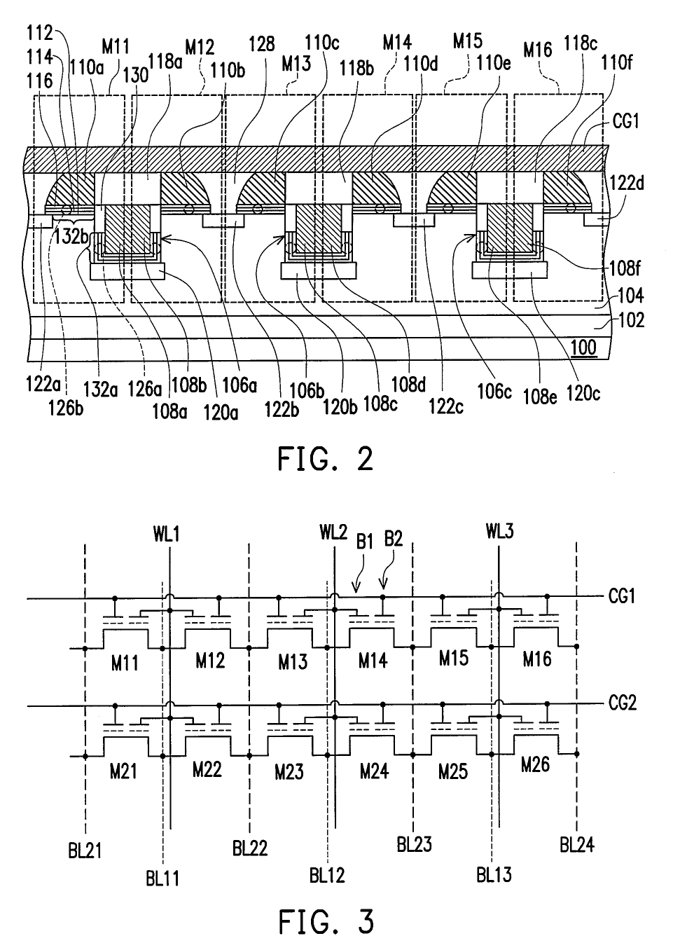

FIG. 1B illustrates schematic cross-sectional view of the non-volatile memory according to another embodiment of the present invention. FIG. 2 illustrates a schematic cross-sectional view along line A-A′ in FIG. 1A. In FIG. 2, the same reference numbers are used to refer to the same parts in FIG. 1A to FIG. 1C and the detailed descriptions are omitted. The following disclosure is directed to the difference between FIG. 2 and FIG. 1A to 1C.

As shown in FIG. 2, a dielectric layer 130 is disposed in the charge storage layer 114 of each of the memory cells M11˜M16. The dielectric layer 130 divides the charge storage layer 114 into the first portion 132a and the second portion 132b. The first portion 132a is located between the first gate 108a and the substrate 100. The second portion 132b is located between the second gate 110a and the substrate 100. The dielectric layer 130 can be disposed to isolate the first bit and the second bit so as to avoid the disturbance between the first bit and the second bit.

In each of the memory cells M11˜M26 of the aforesaid non-volatile memory, the charge storage layers between the first gate and the substrate and between the second gate and the substrate can respectively store one bit of data. In other words, the single memory cell of the present invention can store two bits of data. Moreover, the channel length of the memory cells can be adjusted by controlling the depth of the trench so that the abnormal electrical punch-through in the memory cells can be avoided.

The first gate and the second gate are disposed in each of the memory cells M11˜M26. In the performance of operating these memory cells, the different voltage is applied to the first gate and the second gate to avoid the second bit effect. Besides, the dielectric layer can be disposed in the charge storage layer to isolate the first bit and the second bit so as to avoid the disturbance between the first bit and the second bit.

In the aforementioned embodiment, six memory cells M11˜M16 are serially connected together. Obviously, the number of memory cells serially connected together may suitably vary according to the actual need. For example, 32 to 64 memory cells may be serially connected together in the same word line.

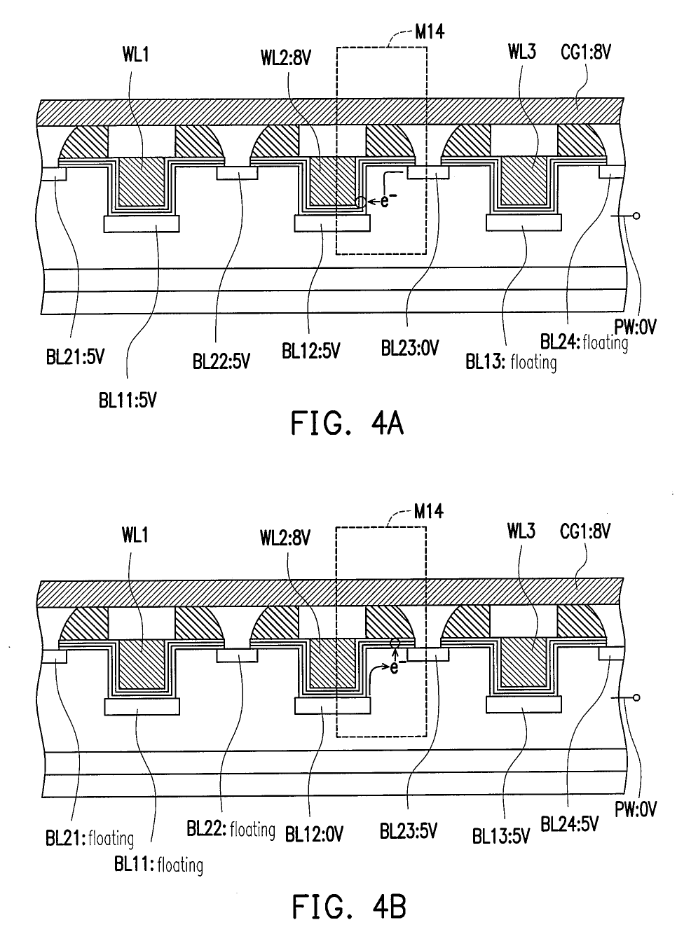

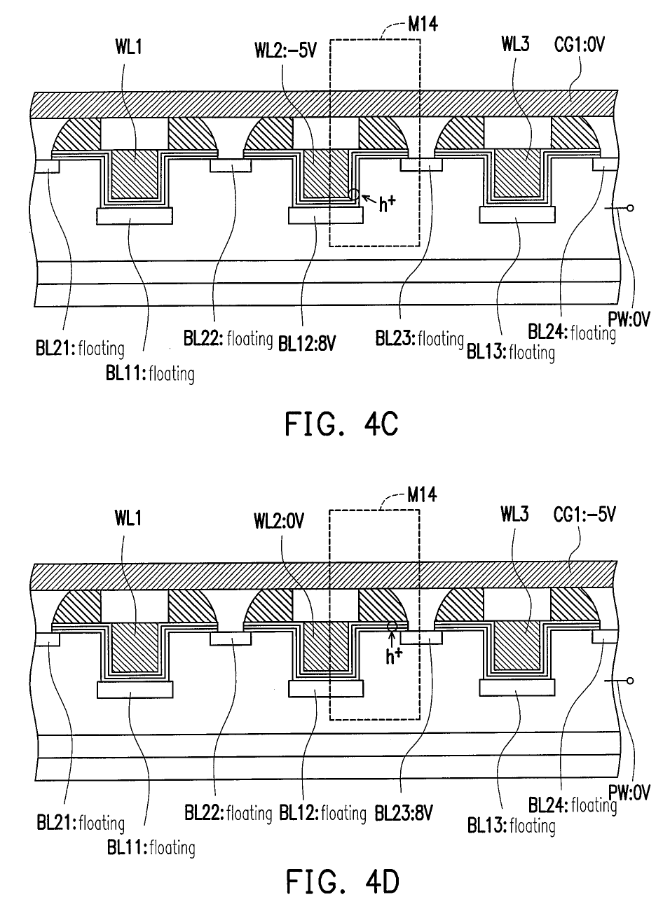

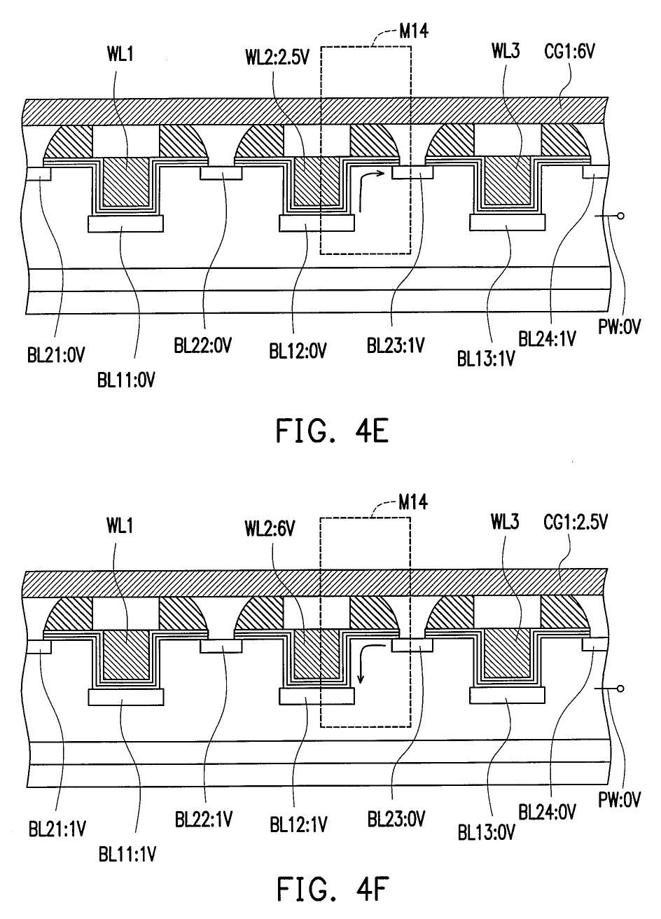

FIG. 3 is a simplified view of circuit illustrating a memory cell array according to one embodiment of the present invention. Here, a memory cell array including 12 memory cells is used as an example to illustrate the operating mode of the memory cell array in the present invention. FIG. 4A is a schematic view illustrating an embodiment of the programming operation of the non-volatile memory according to the present invention. FIG. 4B is a schematic view illustrating another embodiment of the programming operation of the non-volatile memory according to the present invention. FIG. 4C is a schematic view illustrating an embodiment of the reading operation of the non-volatile memory according to the present invention. FIG. 4D is a schematic view illustrating another embodiment of the reading operation of the non-volatile memory according to the present invention. FIG. 4E is a schematic view illustrating an embodiment of the erasing operation of the present invention. FIG. 4F is a schematic view illustrating another embodiment of the erasing operation of the present invention.

Please refer to FIG. 3, the memory cell array includes memory cells M11˜M26, word lines WL1˜WL3, control gate lines CG1˜CG2, first bit lines BL11˜BL13, and second bit lines BL21˜BL24.

Each of the memory cell M11˜M16 includes a first source/drain region and a second source/drain region, a first gate and a second gate serially disposed between the first source/drain region and the second source/drain region, and a charge storage layer disposed between the first gate and the substrate and between the second gate and the substrate. The first gate is electrically insulated against the second gate. The charge store layer between the first gate and the substrate is the first bit B1. The charge store layer between the second gate and the substrate is the second bit B2. Two adjacent memory cells in column direction are configured mirror-systematically and share the first source/drain region or the second source/drain region. The first gates of two adjacent memory cells sharing the first source/drain region in the column direction are electrically connected together.

The first bit lines BL11˜BL13 are arranged in parallel along the row direction and each of the first bit line is connected with the first source/drain region of the memory cells of the same row. The first bit line BL11 is connected to the first source/drain region of the memory cells M11, M12, M21 and M22. The first bit line BL12 is connected to the first source/drain region of the memory cells M13, M14, M23 and M24. The first bit line BL13 is connected to the first source/drain region of the memory cells M15, M16, M25 and M26.

The second bit lines BL21˜BL24 are arranged in parallel along the row direction and each of the second bit lines is connected with the second source/drain region of the memory cells of the same row. The second bit line BL21 is connected to the second source/drain region of the memory cells M11 and M21. The second bit line BL22 is connected to the second source/drain region of the memory cells M12, M13, M22 and M23. The second bit line BL23 is connected to the second source/drain region of the memory cells M14, M15, M24 and M25. The second bit line BL24 is connected to the second source/drain region of the memory cells M16 and M26.

The word lines are arranged in parallel along the row direction, and each of the word lines is connected to the first gate of the memory cells of the same row. For example, the word line WL1 is connected to the first gate of the memory cells M11, M12, M21, and M22. The word line WL2 is connected to the first gate of the memory cells M13, M14, M23, and M24. The word line WL3 is connected to the first gate of the memory cells M15, M16, M25, and M26.

The control gate lines CG1˜CG2 are arranged in parallel along the column direction, and each of the control gate lines is connected to the second gate of the memory cells of the same column. The control gate line CG1 is connected to the second gate of the memory cells M11˜M16. The control gate line CG2 is connected to the second gate of the memory cells M21˜M26.

The operation of the non-volatile memory of the present invention described herein is only a preferred embodiment. However, the method of operating the non-volatile memory is not limited as such. The following description uses the memory cell M14 as an example.

Please refer to FIG. 3 and FIG. 4A. In the programming operation, the first bit B1 of the memory cell M14 is taken as an example, wherein the electrons are stored in the first bit B1. The voltage Vp1 is applied to the selected word line WL2 which is connected to the selected memory cell M14. The voltage Vp1 is between 8˜12V, for example. The voltage Vp2 is applied to the selected control gate line CG1 which is connected to the selected memory cell M14. The voltage Vp2 is between 8˜12V, for example. The voltage Vp3 is applied to the selected first bit line BL12 which is connected to the selected memory cell M14. The voltage Vp3 is about 5V, for example. The voltage Vp4 is applied to the selected second bit line BL23 which is connected to the selected memory cell M14. The voltage Vp4 is about 0V, for example. The voltage Vp5 is applied to the substrate (P-type well, i.e. PW). The voltage Vp5 is about 0V. The voltage Vp6 is applied to the other non-selected first bit line BL11 and second bit lines BL21 and BL22 located at the side of the first bit B1 of the selected memory cell M14. Therefore, the aforesaid method can stop the non-selected memory cells M11˜M13 located at the side of the first bit B1 of the selected memory cell M41 from being programmed. The voltage Vp6 is about 5V. The non-selected first bit line BL13 and second bit line BL24 located at the side of the second bit B2 of the selected memory cell M14 are floating. In this operation, both the voltage Vp1 and Vp2 are higher than the Vp5. The voltage Vp3 is higher than the voltage Vp4. Under the aforesaid bias, the first bit B1 of the selected memory cell M41 is programmed by channel hot electron injection effect.

In the aforesaid operation, since the voltage Vp6 is applied to the first bit line BL11 and the second bit lines BL21 and BL22, the memory cells M11˜M13 sharing the same control gate line CG1 with the memory cell M14 cannot be programmed. Since the first bit line BL13 and the second bit line BL24 are floating, the memory cells M15 and M16 sharing the same control gate line CG1 with the memory cell M14 cannot be programmed. Since no voltage is applied to the control gate line CG2, the memory cells M21˜M26, wherein the memory cells M23˜M24 share the same word line WL2 with the memory cell M14, cannot be programmed.

Please refer to FIG. 3 and FIG. 4B. In the programming operation, the second bit B2 of the memory cell M14 is taken as an example, wherein the electrons are stored in the second bit B2. The voltage Vp7 is applied to the selected word line WL2 which is connected to the selected memory cell M14. The voltage Vp7 is between 8˜12V, for example. The voltage Vp8 is applied to the selected control gate line CG1 which is connected to the selected memory cell M14. The voltage Vp8 is between 8˜12V, for example. The voltage Vp9 is applied to the selected second bit line BL23 which is connected to the selected memory cell M14. The voltage Vp9 is about 5V, for example. The voltage Vp10 is applied to the selected first bit line BL12 which is connected to the selected memory cell M14. The voltage Vp10 is about 0V, for example. The voltage Vp11 is applied to the substrate (P-type well, i.e. PW). The voltage Vp11 is about 0V. The voltage Vp12 is applied to the other non-selected first bit line BL13 and second bit line BL24 located at the side of the second bit B2 of the selected memory cell M14. Therefore, the aforesaid method can stop the non-selected memory cells M15 and M16 located at the side of the second bit B2 of the selected memory cell M41 from being programmed. The voltage Vp12 is about 5V. The non-selected first bit line BL11 and second bit line BL21 and BL22 located at the side of the first bit B1 of the selected memory cell M14 are floating. In this operation, both the voltage Vp7 and Vp8 are higher than the Vp11. The voltage Vp9 is higher than the voltage Vp10. Under the aforesaid bias, the second bit B2 of the selected memory cell M41 is programmed by channel hot electron injection effect.

In the aforesaid operation, since the voltage Vp12 is applied to the first bit line BL13 and the second bit line BL24, the memory cells M15 and M16 sharing the same control gate line CG1 with the memory cell M14 cannot be programmed. Since the first bit line BL11 and the second bit line BL21 and BL22 are floating, the memory cells M11˜M13 sharing the same control gate line CG1 with the memory cell M14 cannot be programmed. Since no voltage is applied to the control gate line CG2, the memory cells M21˜M26, wherein the memory cells M23˜M24 share the same word line WL2 with the memory cell M14, cannot be programmed.

Please refer to FIG. 3 and FIG. 4C. In the erasing operation, the first bit B1 of the memory cell M14 is taken as an example, wherein the first bit B1 is performed with the erasing method. The voltage Ve1 is applied to the selected word line WL2 which is connected to the selected memory cell M14. The voltage Ve1 is about −5V, for example. The voltage Ve2 is applied to the selected control gate line CG1 which is connected to the selected memory cell M14. The voltage Ve2 is about 0V, for example. The voltage Ve3 is applied to the selected first bit line BL12 which is connected to the selected memory cell M14. The voltage Ve3 is about 8V, for example. The selected second bit line BL23 connected with the selected memory cell M14 is floating. The voltage Ve4 is applied to the substrate (P-type well, i.e. PW). The voltage Ve4 is about 0V. The other non-selected first bit lines BL11, BL13 and second bit lines BL21, BL22, BL24 are floating. The Ve3 and Ve1 can induce the band to band hot electron injection effect. The holes are injected into the charge storage layer to erase the first bit B1 of the selected memory cell M14.

In the aforesaid operation, the first bits of the memory cells M13, M23, and M24, which share the same word line WL2 and the first bit line BL12 with the memory cell M14, will be erased at the same time. Therefore, by the voltage Ve1 applied to all the word lines WL1˜WL3 and the voltage Ve3 applied to all the first bit lines BL11˜BL13, the band to band hot electron injection effect can be used to erase the first bit of the memory cells M11˜M26.

Please refer to FIG. 3 and FIG. 4D. In the erasing operation, the second bit B2 of the memory cell M14 is taken as an example, wherein the second bit B2 is performed with the erasing step. The voltage Ve5 is applied to the selected control gate line CG1 which is connected to the selected memory cell M14. The voltage Ve5 is about −5V, for example. The voltage Ve6 is applied to the selected word line WL2 which is connected to the selected memory cell M14. The voltage Ve6 is about 0V, for example. The voltage Ve7 is applied to the selected second bit line BL23 which is connected to the selected memory cell M14. The voltage Ve7 is about 8V, for example. The selected first bit line BL12 connected with the selected memory cell M14 is floating. The voltage Ve8 is applied to the substrate (P-type well, i.e. PW). The voltage Ve8 is about 0V. The other non-selected first bit lines BL11 and BL13 and second bit lines BL21, BL22, and BL24 are floating. The voltage Ve7 and the voltage Ve5 are used to induce the band to band hot electron injection effect to erase the second bit B2 of the selected memory cell M14.

In the aforesaid operation, the second bit of the memory cell M15, which shares the same control gate line CG1 and the second bit line BL23 with the memory cell M14, will be erased at the same time. Therefore, by the voltage Ve5 applied to all the control gate lines CG1˜CG2 and the voltage Ve4 applied to all the second bit lines BL21˜BL24, the band to band hot electron injection effect can be used to erase the second bit of the memory cells M11˜M26.

In the erasing operation, the first bits of all the memory cells can be erased first, and then the second bits of all the memory cells are erased. Or the second bits of all the memory cells are erased first, and then the first bits of all the memory cells are erased.

Please refer to FIG. 3 and FIG. 4E. In the erasing operation, the first bit B1 of the memory cell M14 is taken as an example, wherein the first bit B1 is performed with the reading step. The voltage Vr1 is applied to the selected word line WL2 which is connected to the selected memory cell M14. The voltage Vr1 is about 2.5V, for example. The voltage Vr2 is applied to the selected control gate line CG1 which is connected to the selected memory cell M14. The voltage Vr2 is about 6V, for example. The voltage Vr3 is applied to the selected first bit line BL12 which is connected to the selected memory cell M14. The voltage Vr3 is about 0V, for example. The voltage Vr4 is applied to the selected second bit line BL23 which is connected to the selected memory cell M14. The voltage Vr4 is about 1V, for example. The voltage Vr5 is applied to the substrate (P-type well, i.e. PW). The voltage Vr5 is about 0V. The voltage Vr6 is applied to the non-selected first bit line BL13 and second bit line BL24 located at the side of the second bit B2 of the selected memory cell M14. The voltage Vr6 is about 1V, for example. The voltage Vr7 is applied to the non-selected first bit line BL11 and second bit line BL21 and BL22 located at the side of the first bit B1 of the selected memory cell M14. The voltage Vr7 is about 0V, for example.

Please refer to FIG. 3 and FIG. 4F. In the reading operation, the first bit B2 of the memory cell M14 is taken as an example, wherein the first bit B2 is performed with the reading step. The voltage Vr8 is applied to the selected control gate line CG1 which is connected to the selected memory cell M14. The voltage Vr8 is about 2.5V, for example. The voltage Vr9 is applied to the selected word line WL2 which is connected to the selected memory cell M14. The voltage Vr9 is about 6V, for example. The voltage Vr10 is applied to the selected second bit line BL23 which is connected to the selected memory cell M14. The voltage Vr9 is about 0V, for example. The voltage Vr11 is applied to the selected first bit line BL12 which is connected to the selected memory cell M14. The voltage Vr11 is about 1V, for example. The voltage Vr12 is applied to the substrate (P-type well, i.e. PW). The voltage Vr12 is about 0V. The voltage Vr13 is applied to the non-selected first bit line BL11 and second bit line BL21 and BL22 located at the side of the first bit B1 of the selected memory cell M14. The voltage Vr13 is about 1V, for example. The voltage Vr14 is applied to the non-selected first bit line BL13 and second bit line BL24 located at the side of the second bit B2 of the selected memory cell M14. The voltage Vr14 is about 0V, for example.

In the aforementioned reading operation, the current flowing in a closed channel is weak while memory cells carry negative quantity of charges in the charge storage layer, and the current flowing in an open channel is strong while memory cells carry slightly positive quantity of charges in the charge storage layer. Accordingly, the strength of the current in the channel and the turning-on/turning-off state of the channel can be used to determine whether the digital signal stored in the memory cell is a ‘1’ or a ‘0’.

In the aforesaid operation, the first bit B1 of the memory cell M14 is performed with the reading step.

Since the voltage Vr2 (the voltage is about 6V) is applied to the selected control gate line CG1, the channel under the second gate of the memory cell M14 is completely turned on. Therefore, even the second bit B2 of the memory cell M14 is stored with electrons, the reading process of the first bit B1 is not likely to be affected. Similarly, when reading the first bit B2 of the memory M14, since the Vr9 (the voltage is about 6V) is applied to the selected word line WL2, the channel under the first gate of the memory cell M14 is completely turned on. Therefore, even the first bit B2 of the memory cell M14 is stored with electrons, the reading process of the second bit B2 is not likely to be affected. That is, in the present invention of the non-volatile memory, since the first gate and the second gate are electrically isolated, the second bit effect can be suppressed.

In the operating method for the non-volatile memory of the present invention, the channel hot electron injection effect, wherein the single bit of the single memory cell is the unit, is used to perform the programming of the memory cells. And the band to band hot electron injection is used to perform the erasing of the memory cells. Moreover, since the non-volatile memory cell of the present invention consists of the first gate and the second gate that are electrically isolated, when reading the first bit (or the second bit) of the memory cell, the voltage can be applied to the second gate (or the first gate) so as to completely turn on the channel region under the second gate (or the first gate); therefore, the second bit effect can be suppressed.

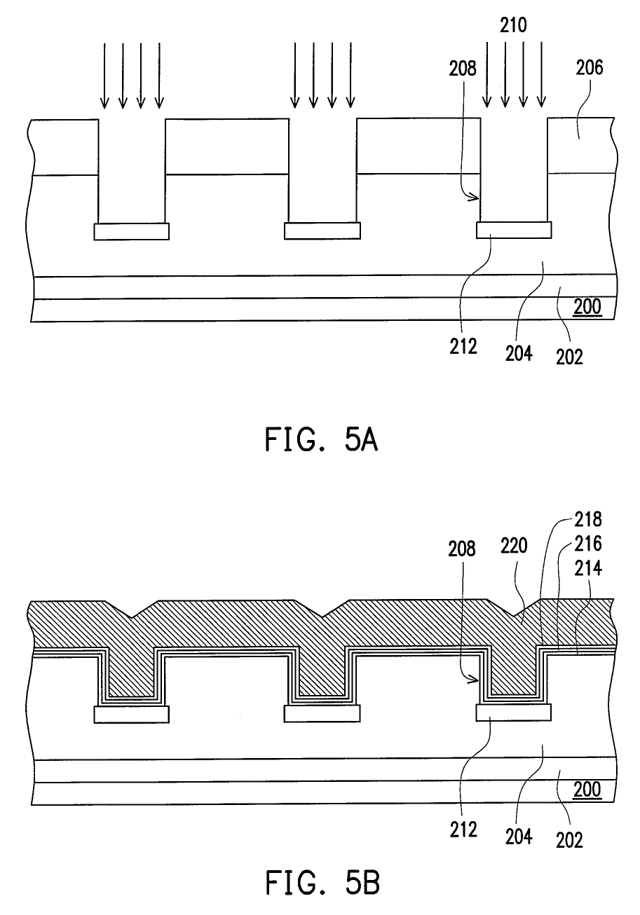

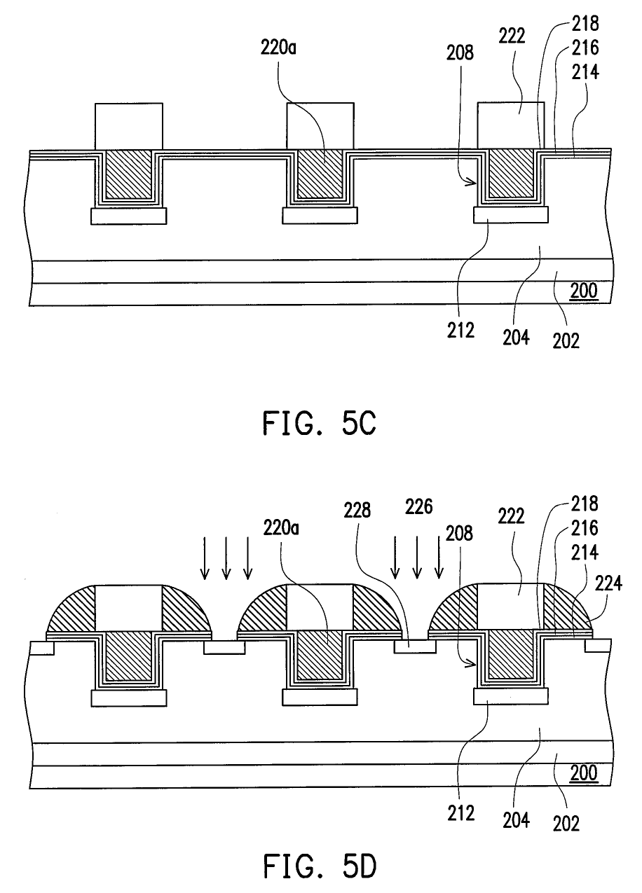

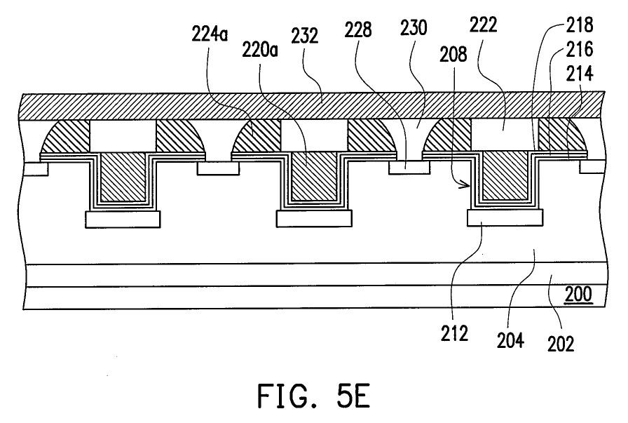

Next, the steps for fabricating the non-volatile memory are described in the following. FIG. 5A to FIG. 5E are schematic cross-sectional views illustrating the manufacturing process of the non-volatile memory according to a preferred embodiment of the present invention. FIGS. 5A to 5E are schematic cross-sectional views along line A-A′ in FIG. 1A.

Referring to FIG. 5A, a substrate 200 is provided, wherein the substrate 200 is, for example, a silicon substrate. Then, a deep N-type well 202 and a P-type well 204 are formed in the substrate 200. The deep N-type well 202 and the p-type well 204 are formed by ion implantation, for example. Next, a patterned mask layer 206 is formed over the substrate 200. Then, a portion of the substrate 200 is removed by using the patterned mask layer 206 as the mask to form a plurality of trenches 208 in the substrate 200. The trenches 208 are formed extensively in the first direction (the Y direction in FIG. 1A). The method to form the patterned mask layer 206 includes, for example, a photolithographic process and an etching process. The method of removing a portion of the substrate 200 includes performing a dry etching operation such as a reactive ion etching operation. Then, the dopant implantation 210 is performed by using the patterned mask layer 206 as a mask, to form first source/drain regions 212 (the first bit line) in the substrate 200 at the bottom of the trenches 208. The method of implanting dopants in the substrate 200 includes an ion implantation.

As shown in FIG. 5B, the patterned mask layer 206 is removed. The method of removing the patterned mask layer 206 includes performing a wet etching process, for example. Next, a bottom dielectric layer 214, a charge storage layer 216, and a top dielectric 218 are sequentially formed on the substrate 200. The material of the bottom dielectric layer 214 is, for example, silicon oxide. The bottom dielectric layer 214 is formed, for example, by a thermal oxidation or chemical vapor deposition process. The material of the charge storage layer 216 includes the charge trapping material (e.g. silicon nitride) or any other materials that can store the charges. The charge storage layer 216 is formed, for example, by performing a chemical vapor deposition (CVD) process. The material of the top dielectric layer 218 is, for example, silicon oxide. The top dielectric layer 218 is formed, for example, by performing a CVD process. Then, a conductive layer 220 is formed over the substrate 200. The material of the conductive layer 220 is, for example, the doped polysilicon. The conductive layer 220 is formed, for example, by depositing an undoped polysilicon layer in a chemical vapor deposition and performing an ion implanting process thereafter. The conductive layer 220 can be formed by using the in-situ dopant implantation and performing the chemical vapor depression process to directly form the doped polysilicon.

Refer to FIG. 5C. The conductive layer 220 outside the trench 208 is removed to form the conductive layers 220a that fill the trench 208. The conductive layers 220a are, for example, served as the first gate of the memory cell in the present invention. The conductive layers 220a are also used as the word line. The method of removing the conductive layer 220 outside the trench 208 includes, for example, performing an etching back process or a chemical-mechanical polishing process. Then, an insulating layer 222 is formed on the conductive layer 220a (the first gate). The insulating layer 222 at least covers the conductive layer 220a (the first gate). The material of the insulating layer 222, for example, is silicon oxide. The steps for forming the insulating layer 222 are as following. First, an insulating material layer (the silicon oxide layer) is formed by the chemical vapor deposition process. Then, the insulating layer (the silicon oxide layer) is patterned by photolithographic process.

Please refer to FIG. 5D. The conductive spacers 224 are formed at the sidewalls of the insulating layer 222. The method for fabricating the conductive spacer 224 is, for example, forming another conductive layer over the substrate 200 first, and performing an anisotropic etching process to remove a portion of the conductive layer and leave behind only the conductive spacer 224 located at the sidewall of the insulating layer 222. The material of the conductive spacer 224 is, for example, doped polysilicon. After the conductive spacers 224 are formed, a portion of the top dielectric layer 218, the charge storage layer 216, and the bottom dielectric layer 214 located between the conductive spacers 224 are removed to expose the surface of the substrate 200. Then, the dopant implantation process 226 is performed by using the conductive spacers 224 as the mask to form the second source/drain regions 228 (the second bit line) in the substrate 200 between the conductive spacers 224. The method of implanting dopants in the substrate 200 includes an ion implantation. The insulating layer 222 is electrically insulated against the conductive layer 220a (the first gate) and the conductive spacer 224.

Next, referring to FIG. 2E, an inter-layer insulating layer 230 is formed on the substrate 200. The inter-layer insulating layer 230 fills the gap between the conductive spacers 224. Then, a portion of inter-layer insulating layer 230 and the insulating layer 222 is removed to expose the conductive spacers 224. The portion of the inter-layer insulating layer 230 and the insulating layer 222 are removed by performing a chemical mechanical polishing process. Then, a conductive layer (not shown) is formed over the substrate 200. The conductive layer is electrically connected with the conductive spacers 224. The material of the conductive layer is, for example, doped polysilicon. The conductive layer 220 is formed, for example, by depositing an undoped polysilicon layer in a chemical vapor deposition process and performing an ion implanting process thereafter. The conductive layer 220 can be formed by using the in-situ dopant implantation and performing the chemical vapor depression process to directly form the doped polysilicon. The conductive layer and the conductive spacers 224 are patterned to form the conductive lines 232 (the control gate line) and the conductive spacers 224a thereunder. The conductive spacers 224a are, for example, used as the second gate of the memory cell in the present invention. The conductive lines 232 are formed extensively in the second direction (the X direction in FIG. 1A). The second direction and the first direction intersect. Then, a dopant implantation process is performed to form isolation doped regions (the isolation doped regions 124 in FIG. 1A) in the substrate 200 between the conductive lines 232. The subsequent process of the memory array is well known to those skilled in the art, and will not be described hereinafter.

In the aforesaid embodiment, since the first source/drain region 212 (the first bit line), the second source/drain region 228 (the second bit line), and the conductive layer 220a (the word line) are self-aligned, no additional photolithographic process is required. Therefore, the fabricating method for the non-volatile memory of the present invention is simpler and reduces the manufacturing cost.

Since a portion of the charge storage layer and the conductive layer 220a (the first gate) are formed in the trench within the substrate, the size of memory cells can be reduced and the integration of the device can be increased. The charge storage layers between the first gate and the substrate and between the second gate and the substrate can respectively store one bit of data. In other words, the single memory cell in the non-volatile memory of the present invention can store two bits of data. Moreover, the channel length of the memory cells can be adjusted by controlling the depth of the trench so that the abnormal electrical punch-through in the memory cells can be avoided. In addition, the fabricating method of the non-volatile memory in the present invention is relatively simpler, and the level of integration of a memory cell array can be increased.

In the aforementioned embodiment, six memory cell structures are taken as examples. Of course, any number of memory cells may be formed as required by using the method of fabricating the non-volatile memory of the present invention. For example, 32 to 64 memory cell structures may be connected in series at a single word line.

In the present invention of the non-volatile memory, the first gate and the second gate are disposed in each memory cell. The charge storage layers between the first gate and the substrate and between the second gate and the substrate can respectively store one bit of data. In other words, the single memory cell in the non-volatile memory of the present invention can store two bits of data.

Moreover, the first gate and the second gate are disposed in each memory cell. In operating the memory cells, the different voltage can be applied to the first gate and the second gate so as to avoid the second bit effect. Besides, the dielectric layer can be disposed in the charge storage layer to isolate the first bit and the second bit so as to avoid the disturbance between the first bit and the second bit.

In the present invention, the charge storage layer and the first gate are disposed in the trench within the substrate. Thus, the size of memory cells can be reduced and the integration of the device can be increased.

In the fabricating method for the non-volatile memory, since the first bit line, the second bit line, the word line are formed by self-alignment process, and the additional photolithographic process is not required, the fabricating method of the present invention is simpler and reduces the cost.

Since a portion of the charge storage layer and the first gate are formed in the trench within the substrate, the size of memory cells can be reduced and the integration of the device can be increased. Moreover, the channel length of the memory cells can be adjusted by controlling the depth of the trench so that the abnormal electrical punch-through in the memory cells can be avoided. In addition, the fabricating method of the non-volatile memory in the present invention is relatively simpler, and the level of integration of a memory cell array can be increased.

In the operating method of the present invention, the channel hot electron injection effect is used to perform the programming of the memory cells, wherein a single bit of a single memory cell is served as a unit. And the band to band hot electron injection is used to perform the erasing of the memory cells. Moreover, since the non-volatile memory cell of the present invention consists of the first gate and the second gate that are electrically isolated, when reading the first bit (or the second bit) of the memory cell, the voltage can be applied to the second gate (or the first gate) so as to completely turn on the channel region under the second gate (or the first gate); therefore, the second bit effect can be suppressed.

Although the present invention has been disclosed above by the preferred embodiments, they are not intended to limit the present invention. Anybody skilled in the art can make some modifications and alteration without departing from the spirit and scope of the present invention. Therefore, the protecting range of the present invention falls in the appended claims.

What is claimed is:

1. A non-volatile memory, comprising:
a substrate having a trench therein;
a first memory cell disposed on the substrate, wherein the first memory cell comprises:
a first gate disposed in the trench;
a second gate disposed on the substrate at one side of the trench;
a charge storage layer disposed extensively between the first gate and the substrate and between the second gate and the substrate;
a first source/drain region disposed in the substrate at the bottom of the trench; and
a second source/drain region disposed in the substrate at one side of the second gate.

2. The non-volatile memory of claim 1, further comprising:
a top dielectric layer disposed between the first gate and the charge storage layer and between the second gate and the charge storage layer.

3. The non-volatile memory of claim 2, wherein the material constituting the top dielectric layer comprises silicon oxide.

4. The non-volatile memory of claim 1, further comprising:
a bottom dielectric layer disposed between the first gate and the substrate and between the second gate and the substrate.

5. The non-volatile memory of claim 4, wherein the material constituting the bottom dielectric layer comprises silicon oxide.

6. The non-volatile memory of claim 1, wherein the material constituting the charge storage layer comprises silicon nitride.

7. The non-volatile memory of claim 1, wherein the material of the first and the second gates comprises doped polysilicon.

8. The non-volatile memory of claim 1, wherein the first gate fills the trench.

9. The non-volatile memory of claim 8, further comprising an insulating layer disposed on the first gate, wherein the first gate is isolated from the second gate by the insulating layer.

10. The non-volatile memory of claim 8, wherein the second gate is a conductive spacer disposed at the sidewall of the insulating layer.

11. The non-volatile memory of claim 8, further comprising a dielectric layer disposed in the charge storage layer and dividing the charge storage layer into a first portion and a second portion, wherein the first portion is located between the first gate and the substrate, and the second portion is located between the second gate and the substrate.

12. The non-volatile memory of claim 1, further comprising a second memory cell having a structure the same as the first memory cell, wherein the first memory cell and the second memory cell are configured mirror-symmetrically.

13. The non-volatile memory of claim 12, wherein the first memory cell and the second memory cell share the first source/drain region or the second source/drain region.

14. The non-volatile memory of claim 12, wherein the second gate of the first memory cell is electrically connected to the second gate of the second memory cell.

15. The non-volatile memory of claim 12, wherein the first memory cell and the second memory cell share the first source/drain region, and the first gate of the first memory cell is electrically connected to the first gate of the second memory cell.

16. A non-volatile memory, comprising:
a plurality of memory cells disposed on a substrate and arranged to form a row/column array, each of the memory cells comprising:
a first source/drain region and a second source/drain region disposed in the substrate;
a first gate and a second gate serially disposed between the first source/drain region and the second source/drain region, wherein the first gate and the second gate are electrically insulated; and
a charge storage layer disposed extensively between the first gate and the substrate and between the second gate and the substrate, wherein two adjacent memory cells in the column direction are configured mirror-systematically and share the first source/drain region or the second source/drain region, and the first gates of two adjacent memory cells sharing the first source/drain region in the column direction are electrically connected;
a plurality of first bit lines arranged in parallel along the row direction and connected with the first source/drain region of the memory cells of the same row;
a plurality of second bit lines arranged in parallel along the row direction and connected with the second source/drain region of the memory cells of the same row;
a plurality of word lines arranged in parallel along the row direction, and connected to the first gate of the memory cells of the same row; and
a plurality of control gate lines arranged in parallel along the column direction, and connected to the second gate of the memory cells of the same column,
wherein the substrate comprises a plurality of trenches therein, and the trenches are arranged in parallel and disposed extensively in row direction; the first gates are respectively disposed in the trenches; the first source/drain regions are respectively disposed in the substrate at the bottom of the trenches; the first bit lines are respectively disposed at the bottom of the trenches; and the word lines respectively fill the trenches.

17. The non-volatile memory of claim 16, wherein the charge storage layers between the first gate and the substrate and between the second gate and the substrate can respectively store one bit of data.

18. The non-volatile memory of claim 16, further comprising:
a top dielectric layer disposed between the first gate and the charge storage layer and between the second gate and the charge storage layer.

19. The non-volatile memory of claim 18, wherein the material constituting the top dielectric layer comprises silicon oxide.

20. The non-volatile memory of claim 16, further comprising:
a bottom dielectric layer disposed between the first gate and the substrate and between the second gate and the substrate.

21. The non-volatile memory of claim 20, wherein the material constituting the bottom dielectric layer comprises silicon oxide.

22. The non-volatile memory of claim 16, wherein the material constituting the charge storage layer comprises silicon nitride.

23. The non-volatile memory of claim 16, wherein the material of the first and the second gates comprises doped polysilicon.

24. The non-volatile memory of claim 16, further comprising a plurality of insulating layers respectively disposed on the word lines, wherein the first gate is isolated from the second gate by the insulating layers.

25. The non-volatile memory of claim 24, wherein the second gates are conductive spacers disposed on the sidewalls of the insulating layers.

26. The non-volatile memory of claim 16, further comprising a top dielectric layer disposed in the charge storage layer and dividing the charge storage layer into a first portion and a second portion, wherein the first portion is located between the first gate and the substrate, and the second portion is located between the second gate and the substrate.

27. The non-volatile memory of claim 16, further comprising a plurality of isolation doped regions disposed in the substrate between the control gate lines to isolate two adjacent memory cells of the same row.

28. A method of fabricating a non-volatile memory, comprising:
providing a substrate;
forming a plurality of trenches in the substrate, wherein the trenches are disposed extensively in a first direction;
forming a plurality of first source/drain regions in the substrate at the bottom of the trenches;
forming a charge storage layer on the substrate;
forming a first gate in the trenches respectively;
forming an insulating layer on the first gates respectively;
forming a plurality of conductive spacers on sidewalls of the insulating layers;
forming a plurality of second source/drain regions in the substrate between the conductive spacers;
forming an inter-layer insulating layer on the second source/drain regions;
forming a conductive layer on the substrate, wherein the conductive spacers are electrically connected; and
patterning the conductive layer and the conductive spacers to form a plurality of conductive lines and the second gates thereunder, wherein the conductive lines are disposed extensively in the second direction, and the first direction and the second direction intersect.

29. The method of claim 28, wherein the steps of forming the first gates in the trenches respectively comprise:
forming a first conductive layer over the substrate, wherein the first conductive layer completely fills the trenches; and
removing a portion of the first conductive layer outside the trenches.

30. The method of claim 29, wherein the step of removing a portion of the first conductive layer outside the trenches comprises performing etching back process or chemical mechanical polishing process.

31. The method of claim 28, wherein the steps of respectively forming the insulating layer on the first gates comprise:
forming an insulating material layer over the substrate; and
patterning the insulating material layer.

32. The method of claim 28, wherein the steps of forming the conductive spacers on the sidewalls of the insulating layers comprise:
forming a second conductive layer over the substrate; and
performing the anisotropic etching process to remove a portion of the second conductive layer.

33. The method of claim 28, further comprising removing a portion of the charge storage layer to expose the substrate during the step of performing the anisotropic etching process to remove a portion of the second conductive layer.

34. The method of claim 28, further comprising forming a plurality of isolation doped regions in the substrate between two adjacent conductive lines.

35. The method of claim 28, further comprising forming a bottom dielectric layer on the substrate before the step of forming the charge storage layer on the substrate.

36. The method of claim 35, wherein the material constituting the bottom dielectric layer comprises silicon oxide.

37. The method of claim 28, further comprising forming a top dielectric layer on the charge storage layer after the step of forming the charge storage layer on the substrate.

38. The method of claim 37, wherein the material of the top dielectric layer comprises silicon oxide.

39. The method of claim 28, wherein the material of the charge storage layer comprises silicon nitride.

40. The method of claim 28, wherein a material of the first gate and the second gate comprises doped polysilicon.

41. A method of fabricating a non-volatile memory, comprising:
providing a substrate;
forming a trench in the substrate;
forming a first source/drain region at the bottom of the trenches;
forming a charge storage layer on the substrate;
forming a first gate in the trenches;
forming a second gate on the substrate, wherein the second gate is adjacent to the first gate, and the second gate is electrically against the first gate; and
forming a second source/drain region in the substrate at one side of the second gate.

42. The method of claim 41, wherein the steps of forming the first gate in the trench comprise:
forming a first conductive layer over the substrate, wherein the first conductive layer completely fills the trench; and
removing a portion of the first conductive layer outside the trench.

43. The method of claim 42, wherein the step of removing a portion of the first conductive layer outside the trench comprises performing etching back process or chemical mechanical polishing process.

44. The method of claim 41, further comprising a step of forming an insulating layer between the first gate and the second gate.

45. The method of claim 41, further comprising forming a bottom dielectric layer on the substrate before the step of forming the charge storage layer on the substrate.

46. The method of claim 45, wherein the material constituting the bottom dielectric layer comprises silicon oxide.

47. The method of claim 41, further comprising forming a top dielectric layer on the charge storage layer after the step of forming the charge storage layer on the substrate.

48. The method of claim 47, wherein the material of the top dielectric layer comprises silicon oxide.

49. The method of claim 41, wherein the material of the charge storage layer comprises silicon nitride.

50. The method of claim 41, wherein the material of the first gate and the second gate comprises doped polysilicon.

51. A method for operating the non-volatile memory, suitable for a memory cell array comprising: a plurality of memory cells, each of the memory cells comprising a first source/drain region and a second source/drain region disposed in a substrate, a first gate and a second gate serially disposed between the first source/drain region and the second source/drain region, and the charge storage layer disposed between the first gate and the substrate and between the second gate and the substrate, wherein the substrate comprises a plurality of trenches therein, and the trenches are arranged in parallel and disposed extensively in row direction, the first gates are respectively disposed in the trenches, the first source/drain regions are respectively disposed in the substrate at the bottom of the trenches, the first gate and the second gate are electrically isolated, the charge storage layer between the first gate and the substrate is a first bit, the charge storage layer between the second gate and the substrate is a second bit, two adjacent memory cells in the column direction are configured mirror-systematically and share the first source/drain region and the second source/drain region, and the first gates of two adjacent memory cells sharing the first source/drain region are electrically connected; a plurality of first bit lines, arranged in parallel along the row direction and connected with the first source/drain region of the memory cells of the same row; a plurality of second bit lines, arranged in parallel along the row direction and connected with the second source/drain region of the memory cells of the same row; a plurality of word lines, arranged in parallel along the row direction and connected with the first gate of the memory cells of the same row; and a plurality of control gate lines, arranged in parallel along the row direction and connected with the second gate of the memory cells of the same row; the steps comprising:
applying a first voltage to a selected word line connected with a selected memory cell; applying a second voltage to a selected control gate line connected with the selected memory cell; applying a third voltage to a selected first bit line connected with the selected memory cell; applying a fourth voltage to a selected second bit line connected with the selected memory cell; applying a fifth voltage to the substrate; applying a sixth voltage to the other non-selected first bit lines and selected second bit lines located at the side of the first bit of the selected memory cell; and floating the other non-selected first bit lines and second bit lines disposed at the side of the second bit of the selected memory cell while performing a programming operation, wherein the first voltage and the second voltage are higher than the fifth voltage, and the third voltage is higher than the fourth voltage to program the first bit of the selected memory cell by channel hot electron injection effect, and the sixth voltage prevents the non-selected memory cells disposed at the side of the first bit of the memory cell from being programmed.

52. The method of claim 51, wherein the first voltage is about 8˜12V, the second voltage is about 8˜12V, the third voltage is about 5V, the fourth voltage is about 0V, the fifth voltage is about 0V, and the sixth voltage is about 5V.

53. The method of claim 51, further comprising applying a seventh voltage to a selected word line connected with the selected memory cell; applying a eighth voltage to the selected control gate line connected with the selected memory cell; applying a ninth voltage to the selected second bit line connected with the selected memory cell; applying a tenth voltage to the selected first bit line connected with the selected memory cell; applying a eleventh voltage to the substrate; applying a twelfth voltage to the other non-selected first bit lines and second bit lines located at the side of the second bit of the selected memory cell; floating the other non-selected first bit lines and second bit lines disposed at the side of the first bit of the selected memory cell while performing a programming operation, wherein the seventh voltage and the eighth voltage are higher than the eleventh voltage, and the ninth voltage is higher than the tenth voltage to program the second bit of the selected memory cell by channel hot electron injection effect and the twelfth voltage prevents the non-selected memory cells disposed at the side of the second bit of the selected memory cell from being programmed.

54. The method of claim 53, wherein the seventh voltage is about 8˜12V, the eighth voltage is about 8˜12V, the ninth voltage is about 5V, the tenth voltage is about 0V, the eleventh voltage is about 0V, and the twelfth voltage is about 5V.

55. The method of claim 51, further comprising applying a thirteenth voltage to the selected word line connected with the selected memory cell; applying a fourteenth voltage to the selected control gate line connected with the selected memory cell; applying a fifteenth voltage to the selected first bit line connected with the selected memory cell; floating the selected second bit line connected with the memory cell; applying a sixteenth voltage to the substrate; floating the other non-selected first bit lines and second bit lines while performing an erasing operation, wherein the fifteenth voltage and the thirteenth voltage can induce the band to band hot electron injection effect to erase the first bit of the selected memory cell.

56. The method of claim 55, wherein the thirteenth voltage is about −5V, the fourteenth voltage is about 0V, the fifteenth voltage is about 8V, and the sixteenth voltage is about 0V.

57. The method of claim 51, further comprising applying a seventeenth voltage to the selected control gate line connected with the selected memory cell; applying an eighteenth voltage to the selected word line connected with the selected memory cell; applying a nineteenth voltage to the selected second bit line connected with the selected memory cell; floating the selected first bit line connected with the memory cell; applying a twentieth voltage to the substrate; floating the other non-selected first bit lines and second bit lines while performing an erasing operation, wherein the nineteenth voltage and the seventeenth voltage can induce the band to band hot electron injection effect to erase the second bit of the selected memory cell.

58. The method of claim 57, wherein the seventeenth voltage is about −5 V, the eighteenth voltage is about 0V, the nineteenth voltage is about 8V, and the twentieth voltage is about 0 V.

59. The method of claim 51, further comprising applying a twenty-first voltage to the selected word line connected with the selected memory cell; applying a twenty-second voltage to the selected control gate line connected with the selected memory cell; applying a twenty-third voltage to the selected first bit line connected with the selected memory cell; applying a twenty-fourth voltage to the selected second bit line connected with the selected memory cell; applying a twenty-fifth voltage to the substrate; applying a twenty-sixth voltage to the other non-selected first bit lines and second bit lines disposed at the side of the second bit of the selected memory cell; applying a twenty-seventh voltage to the other non-selected first bit lines and second bit lines disposed at the side of the first bit of the selected memory cell to read the first bit while performing a reading operation, wherein the twenty-first voltage is higher than the threshold voltage of the memory cells without any trapped electron and lower than threshold voltage of the memory cells with electron, the twenty-second voltage is sufficient to turn on the channel region under the second gate, the twenty-fourth voltage is higher than the twenty-third voltage, the twenty-sixth voltage is equal to the twenty-fourth voltage, and the twenty-seventh voltage is equal to the twenty-third voltage.

60. The method of claim 59, wherein the twenty-first voltage is about 2.5V, the twenty-second voltage is about 6V, the twenty-third voltage and the twenty-seventh voltage are about 0V, the twenty-fourth voltage and the twenty-sixth voltage are about 1V, and the twenty-fifth voltage is about 0V.

61. The method of claim 51, further comprising applying a twenty-eighth voltage to the selected control gate line connected with the selected memory cell; applying a twenty-ninth voltage to the selected word line connected with the selected memory cell; applying a thirtieth voltage to the selected second bit line connected with the selected memory cell; applying a thirty-first voltage to the selected first bit line connected with the selected memory cell; applying a thirty-second voltage to the substrate; applying a thirty-third voltage to the other non-selected first bit lines and second bit lines disposed at the side of the first bit of the selected memory cell; applying a thirty-fourth voltage to the other non-selected first bit lines and second bit lines disposed at the side of the second bit of the selected memory cell to read the first bit while performing a reading operation, wherein the twenty-eighth voltage is higher than the threshold voltage of the memory cells without any trapped electron and lower than threshold voltage of the memory cells with electron, the twenty-ninth voltage is sufficient to turn on the channel region under the second gate, the thirty-first voltage is higher than the thirty voltage, the thirty-fourth voltage is equal to the thirty voltage, and the thirty-third voltage is equal to the thirty-first voltage.

62. The method of the claim 61, wherein the twenty-eighth voltage is about 2.5V, the twenty-ninth voltage is about 6V, the thirtieth voltage and the thirty-fourth voltage are about 0V, the thirty-third voltage and the thirty-first voltage are about 1V, and the thirty-second voltage is about 0V.
